(19) United States
(12) Patent Application Publication
(10) Pub. No.: US 2026/0239707 A1
(43) Pub. Date: Aug. 13, 2026

(54) SEMICONDUCTOR DEVICE

(71) Applicants: KABUSHIKI KAISHA TOSHIBA, Kawasaki-shi (JP); Toshiba Electronic Devices & Storage Corporation, Kawasaki-shi (JP)

(72) Inventor: Toshifumi NISHIGUCHI, Hakusan Ishikawa (JP)

(73) Assignees: KABUSHIKI KAISHA TOSHIBA, Kawasaki-shi (JP); Toshiba Electronic Devices & Storage Corporation, Kawasaki-shi (JP)

(21) Appl. No.: 19/346,602

(22) Filed: Oct. 1, 2025

(30) Foreign Application Priority Data
Feb. 10, 2025 (JP) 2025-020297

(51) Int. Cl. H10D 64/00; H10D 30/01; H10D 30/66; H10D 64/23

(52) U.S. Cl. CPC H10D 64/118; H10D 30/0297; H10D 30/668; H10D 64/117; H10D 64/2527

(57) ABSTRACT

A semiconductor device includes first and second electrodes, a semiconductor layer with a first and second semiconductor regions, a third semiconductor region of a first conductivity type, and third and fourth electrodes. The first semiconductor region is located on the first electrode. The second semiconductor region is located on the first semiconductor region. The third semiconductor region is located between the second semiconductor region and the second electrode. The third electrode faces the second semiconductor region via a first insulating region. The fourth electrode is in the first semiconductor region via a second insulating region and is electrically connected to the second electrode. The second insulating region includes a first and second portions located between the first semiconductor region and the fourth electrode in a first direction and a second direction, respectively. A dielectric constant of the second portion is lower than that of the first portion.

### CROSS-REFERENCE TO RELATED APPLICATION

This application is based upon and claims the benefit of priority from Japanese Patent Application No. 2025-020297, filed Feb. 10, 2025, the entire contents of which are incorporated herein by reference.

### FIELD

Embodiments described herein relate generally to a semiconductor device.

### BACKGROUND

In a semiconductor device such as a metal oxide semiconductor field effect transistor (MOSFET), a low on-resistance is desirable. For example, in a semiconductor device in which a field plate electrode is provided in a trench via an insulating film (field plate insulating film), it is conceivable to shorten a distance between adjacent field plate electrodes (cell pitch) to reduce an on-resistance. However, in a semiconductor device for high-breakdown voltage application, since a thicker field plate insulating film is required, there is a limit to shortening the distance between adjacent field plate electrodes.

Examples of related art include JP-B-7106476 and JP-B-5480791.

### DESCRIPTION OF THE DRAWINGS

FIG. 1 is a cross-sectional view of a semiconductor device according to a first embodiment;

FIG. 2 is an enlarged view of a region A1 in FIG. 1;

FIG. 3A is a cross-sectional view illustrating an example of a manufacturing process of the semiconductor device according to the first embodiment;

FIG. 3B is a cross-sectional view subsequent to FIG. 3A illustrating an example of the manufacturing process of the semiconductor device according to the first embodiment;

FIG. 3C is a cross-sectional view subsequent to FIG. 3B illustrating an example of the manufacturing process of the semiconductor device according to the first embodiment;

FIG. 3D is a cross-sectional view subsequent to FIG. 3C illustrating an example of the manufacturing process of the semiconductor device according to the first embodiment;

FIG. 3E is a cross-sectional view subsequent to FIG. 3D illustrating an example of the manufacturing process of the semiconductor device according to the first embodiment;

FIG. 3F is a cross-sectional view subsequent to FIG. 3E illustrating an example of the manufacturing process of the semiconductor device according to the first embodiment;

FIG. 3G is a cross-sectional view subsequent to FIG. 3F illustrating an example of the manufacturing process of the semiconductor device according to the first embodiment;

FIG. 3H is a cross-sectional view subsequent to FIG. 3G illustrating an example of the manufacturing process of the semiconductor device according to the first embodiment;

FIG. 3I is a cross-sectional view subsequent to FIG. 3H illustrating an example of the manufacturing process of the semiconductor device according to the first embodiment;

FIG. 3J is a cross-sectional view subsequent to FIG. 3I illustrating an example of the manufacturing process of the semiconductor device according to the first embodiment;

FIG. 3K is a cross-sectional view subsequent to FIG. 3J illustrating an example of the manufacturing process of the semiconductor device according to the first embodiment;

FIG. 4 is a cross-sectional view of a semiconductor device according to Modification 1 of the first embodiment;

FIG. 5 is a cross-sectional view of a semiconductor device according to Modification 2 of the first embodiment;

FIG. 6 is a cross-sectional view of a semiconductor device according to a second embodiment;

FIG. 7 is an enlarged view of a region A2 in FIG. 6;

FIG. 8A is a cross-sectional view illustrating an example of a manufacturing process of the semiconductor device according to the second embodiment;

FIG. 8B is a cross-sectional view subsequent to FIG. 8A illustrating an example of the manufacturing process of the semiconductor device according to the second embodiment;

FIG. 8C is a cross-sectional view subsequent to FIG. 8B illustrating an example of the manufacturing process of the semiconductor device according to the second embodiment;

FIG. 8D is a cross-sectional view subsequent to FIG. 8C illustrating an example of the manufacturing process of the semiconductor device according to the second embodiment;

FIG. 8E is a cross-sectional view subsequent to FIG. 8D illustrating an example of the manufacturing process of the semiconductor device according to the second embodiment;

FIG. 8F is a cross-sectional view subsequent to FIG. 8E illustrating an example of the manufacturing process of the semiconductor device according to the second embodiment;

FIG. 8G is a cross-sectional view subsequent to FIG. 8F illustrating an example of the manufacturing process of the semiconductor device according to the second embodiment;

FIG. 8H is a cross-sectional view subsequent to FIG. 8G illustrating an example of the manufacturing process of the semiconductor device according to the second embodiment;

FIG. 8I is a cross-sectional view subsequent to FIG. 8H illustrating an example of the manufacturing process of the semiconductor device according to the second embodiment;

FIG. 8J is a cross-sectional view subsequent to FIG. 8I illustrating an example of the manufacturing process of the semiconductor device according to the second embodiment;

FIG. 8K is a cross-sectional view subsequent to FIG. 8J illustrating an example of the manufacturing process of the semiconductor device according to the second embodiment; and

FIG. 9 is a cross-sectional view of a semiconductor device according to Modification of the second embodiment.

### DETAILED DESCRIPTION

Embodiments provide a semiconductor device capable of reducing on-resistance.

In general, according to one embodiment, a field plate MOSFET semiconductor device includes a first electrode having a main surface that extends along a second direction; a second electrode; a semiconductor layer between the first electrode and the second electrode; a gate electrode at least partially disposed in the semiconductor layer; a field plate electrode disposed in a region of the semiconductor layer between the gate electrode and the first electrode, the field plate being electrically connected to the second electrode; and a field plate insulating region that includes a first insulating material disposed along a bottom of the field plate electrode oriented along the second direction, and a second insulating material disposed along at least a portion of a side of the field plate electrode in a first direction perpendicular to the second direction, wherein a dielectric constant of the second insulating material is lower than a dielectric constant of the first insulating material.

Hereinafter, embodiments of the present disclosure will be described with reference to the drawings. The present disclosure is not limited to the embodiments. The drawings are schematic or conceptual, and proportions and the like of various parts are not necessarily the same as the actual proportions and the like. In the specification and drawings, elements similar to those already described with reference to the previous drawings are given the same reference numerals, and detailed descriptions thereof will be omitted as appropriate.

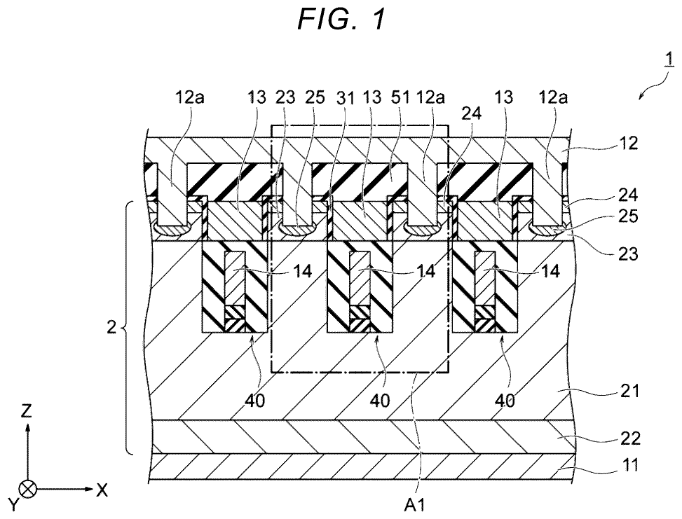

For convenience of explanation, an XYZ orthogonal coordinate system is adopted as shown in FIG. 1 and the like. A Z-axis direction is a stacking direction (thickness direction) of a semiconductor device. A source electrode side in the Z-axis direction is also called “upper” and a drain electrode side is also called “lower”. However, the expressions are for convenience and have no relation to the direction of gravity. The Z-axis direction is a first direction. An X-axis direction is a second direction. A Y-axis direction is a third direction.

In the following explanation, the notations n⁺, n, n⁻, p⁺, p, and p⁻ may be used to indicate relative levels of impurity concentration in each of conductivity types. That is, n⁺ indicates that an n-type impurity concentration is relatively higher than n, and n⁻ indicates that an n-type impurity concentration is relatively lower than n. p⁺ indicates that a p-type impurity concentration is relatively higher than p, and p⁻ indicates that a p-type impurity concentration is relatively lower than p. When both p-type and n-type impurities are contained in the regions, the notations indicate the relative level of the net impurity concentration after impurities compensate for each other. n-type, n⁺ type, and n⁻ type are examples of a first conductivity type. p-type, p⁺ type, and p⁻ type are examples of a second conductivity type. In the following description, n-type and p-type may be reversed. In other words, the first conductivity type may be p-type.

The impurity concentration of a semiconductor region can be measured, for example, by secondary ion mass spectrometry (SIMS). The relative level of the impurity concentration can also be determined, for example, from the level of carrier concentration determined by scanning capacitance microscopy (SCM).

Dimensions of the semiconductor region such as a width can be measured by surface and/or cross-sectional analysis using, for example, a transmission electron microscope (TEM), energy dispersive X-ray spectroscopy (EDX), or a scanning electron microscope (SEM).

In the specification, terms such as “same” and “identical” that specify shapes, geometric conditions, physical characteristics, and levels thereof as well as dimensions and values of physical characteristics are interpreted to include the extent to which similar functions can be expected without being bound by strict meanings.

### First Embodiment

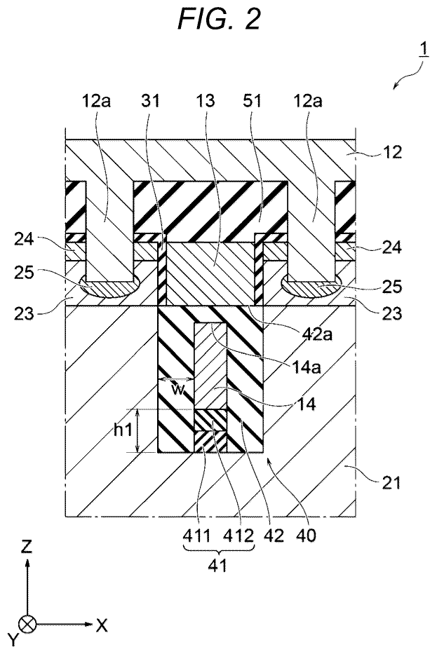

A semiconductor device 1 according to a first embodiment will be described with reference to FIGS. 1 and 2. FIG. 1 is a cross-sectional view of the semiconductor device 1 according to the first embodiment. FIG. 2 is an enlarged view of a region A1 in FIG. 1.

The semiconductor device 1 is, for example, a vertical MOSFET. More specifically, the semiconductor device 1 is a vertical MOSFET having a structure in which a gate electrode and a field plate electrode (FP electrode) are provided in the same trench. The semiconductor device 1 may have a structure in which a gate electrode 13 and an FP electrode 14 are provided in different trenches.

As shown in FIG. 1, the semiconductor device 1 of the present embodiment includes a semiconductor layer 2, a drain electrode 11, a source electrode 12, and an interlayer insulating film 51.

The semiconductor layer 2 is provided between the drain electrode 11 and the source electrode 12. The semiconductor layer 2 has a lower surface and an upper surface opposite to the lower surface. Various semiconductor regions described later are provided in the semiconductor layer 2.

The semiconductor layer 2 may be an epitaxial layer, a semiconductor substrate, or a semiconductor substrate and an epitaxial layer disposed on the semiconductor substrate. In the present embodiment, the semiconductor layer 2 is silicon (Si). Here, for example, arsenic (As), phosphorus (P), or antimony (Sb) is used as an n-type impurity, and for example, boron (B) is used as a p-type impurity. The semiconductor layer 2 may be made of a compound semiconductor such as silicon carbide (SiC) or gallium nitride (GaN).

The drain electrode 11 functions as a drain electrode of the MOSFET. The drain electrode 11 is provided on the lower surface of the semiconductor layer 2. The drain electrode 11 is in ohmic contact with, for example, a drain region 22. The drain electrode 11 includes, for example, at least one of copper (Cu), titanium (Ti), tungsten (W), and aluminum (Al). The drain electrode 11 is an example of a first electrode.

The source electrode 12 functions as a source electrode of the MOSFET. The source electrode 12 is provided on the upper surface of the semiconductor layer 2 via the interlayer insulating film 51. The source electrode 12 includes a contact portion 12a that protrudes downward. The contact portion 12a penetrates the interlayer insulating film 51, a gate insulating film 31, and a source region 24, and reaches a high-concentration region 25. The source electrode 12 is in ohmic contact with, for example, the source region 24 and the high-concentration region 25 via the contact portion 12a. The source electrode 12 includes, for example, at least one of copper (Cu), titanium (Ti), tungsten (W), and aluminum (Al). The source electrode 12 is an example of a second electrode.

The interlayer insulating film 51 is provided on the gate electrode 13 and the gate insulating film 31, and electrically insulates the gate electrode 13 from the source electrode 12. The interlayer insulating film 51 includes, for example, silicon oxide or silicon nitride.

A configuration of inside of the semiconductor layer 2 will be described below.

The gate electrode 13, the FP electrode 14, a drift region 21, the drain region 22, a base region 23, the source region 24, the high-concentration region 25, the gate insulating film 31, and a field plate insulating film (FP insulating film) 40 are provided in the semiconductor layer 2.

The gate electrode 13 functions as a gate electrode of the MOSFET. The gate electrode 13 is provided to face the base region 23 via the gate insulating film 31. In the present embodiment, the gate electrode 13 is provided in the base region 23 via the gate insulating film 31. The gate electrode 13 is electrically insulated from the semiconductor layer 2 by the gate insulating film 31. In the present embodiment, the gate electrode 13 is located above the FP electrode 14. The gate electrode 13 extends in the Y-axis direction. The gate electrode 13 is made of, for example, polysilicon containing a p-type impurity or an n-type impurity. When a voltage is applied to the gate electrode 13, a channel is formed in the base region 23, and carriers (electrons in the present embodiment) flow between the drift region 21 (drain region 22) and the source region 24. Accordingly, the MOSFET enters an on state. The gate electrode 13 is an example of a third electrode.

The FP electrode 14 is provided in the drift region 21 via the FP insulating film 40, which includes different insulating materials, as will be discussed. The FP electrode 14 is electrically insulated from the semiconductor layer 2 and the gate electrode 13 by the FP insulating film 40. The FP electrode 14 is electrically connected to the source electrode 12 at an end of the semiconductor device 1 or the like (not shown). The FP electrode 14 extends in the Y-axis direction. The FP electrode 14 is made of, for example, polysilicon containing a p-type impurity or an n-type impurity. By providing the FP electrode 14, when the semiconductor device 1 is in an off state, a depletion layer extends from the FP insulating film 40 in which the FP electrode 14 is disposed to the surrounding drift region 21 due to a reverse voltage applied between the drain electrode 11 and the source electrode 12. The depletion layer connects to the depletion layer extending from the FP insulating film 40 in which the adjacent FP electrode 14 is disposed, thereby improving a breakdown voltage of the semiconductor device 1. The FP electrode 14 is an example of a fourth electrode.

The drift region 21 functions as a drift region of the MOSFET. The drift region 21 is disposed above the drain region 22 (above the drain electrode 11). The drift region 21 is, for example, an n⁻ type semiconductor region. An n-type impurity concentration of the drift region 21 is, for example, 1×10¹⁵ cm⁻³ or more and 2×10¹⁶ cm⁻³ or less.

The drain region 22 functions as a drain region of the MOSFET. The drain region 22 is located on the drain electrode 11 and is disposed between the drift region 21 and the drain electrode 11. The drain region 22 is in contact with the drain electrode 11 and is electrically connected to the drain electrode 11. The drain region 22 is, for example, an n⁺ type semiconductor region. An n-type impurity concentration of the drain region 22 is, for example, 1×10¹⁸ cm⁻³ or more and 1×10²¹ cm⁻³ or less.

The drift region 21 and the drain region 22 are both examples of a first semiconductor region. The drain region 22 may not be provided. Then, the drift region 21 is provided directly on the drain electrode 11, and the drain electrode 11 is electrically connected to the drift region 21. Alternatively, the drift region 21 may not be provided. Then, for example, the drain region 22 is provided also at the position of the drift region 21.

The base region 23 functions as a base region of the MOSFET. The base region 23 is located on the drift region 21. The base region 23 is, for example, a p-type semiconductor region. An p-type impurity concentration of the base region 23 is, for example, 1×10¹⁶ cm⁻³ or more and 1×10²⁰ cm⁻³ or less. The base region 23 is an example of a second semiconductor region.

The source region 24 functions as a source region of the MOSFET. The source region 24 is located between the base region 23 and the source electrode 12. The source region 24 is in contact with the contact portion 12a and is electrically connected to the source electrode 12 via the contact portion 12a. The source region 24 is, for example, an n⁺ type semiconductor region. An n-type impurity concentration of the source region 24 is, for example, 1×10¹⁸ cm⁻³ or more and 1×10²² cm⁻³ or less. The source region 24 is an example of a third semiconductor region.

The high-concentration region 25 is provided in the base region 23 and surrounds a lower end of the contact portion 12a. The high-concentration region 25 is in contact with the contact portion 12a and is electrically connected to the source electrode 12 via the contact portion 12a. The high-concentration region 25 is, for example, a p⁺ type semiconductor region. That is, an impurity concentration of the high-concentration region 25 is higher than the impurity concentration of the base region 23. The p-type impurity concentration of the high-concentration region 25 is, for example, 1×10¹⁸ cm⁻³ or more and 1×10²¹ cm⁻³ or less. By providing the high-concentration region 25, minority carriers (holes in the present embodiment) remaining in the base region 23 are easily discharged to the source electrode 12 via the contact portion 12a. Accordingly, it is possible to improve avalanche resistance of the semiconductor device 1.

The gate insulating film 31 electrically insulates the gate electrode 13 from the semiconductor layer 2. In the present embodiment, the gate insulating film 31 is provided on a side surface of the gate electrode 13 and the upper surface of the semiconductor layer 2. In the present embodiment, the gate insulating film 31 is located on the FP insulating film 40. The gate insulating film 31 includes, for example, silicon oxide or silicon nitride. The gate insulating film 31 is an example of a first insulating region.

The FP insulating film 40 is provided in the drift region 21, and the FP electrode 14 is disposed inside. The FP insulating film 40 is an example of a second insulating region (or a field plate insulating region). Details of the FP insulating film 40 will be described below.

As shown in FIG. 2, in the present embodiment, the FP insulating film 40 includes a first portion 41 (sometimes called a first insulating material) and a second portion 42 (sometimes called a second insulating material).

The first portion 41 is at least a portion of the FP insulating film 40 and is provided directly under the FP electrode 14. That is, the first portion 41 is located between the drift region 21 and the FP electrode 14 in the Z-axis direction. In other words, the first portion 41 is interposed between the drift region 21 and the FP electrode 14 in the Z-axis direction.

The second portion 42 is at least a portion of the FP insulating film 40 and is provided next to the FP electrode 14. That is, the second portion 42 is located between the drift region 21 and the FP electrode 14 in the X-axis direction. In other words, the second portion 42 is interposed between the drift region 21 and the FP electrode 14 in the X-axis direction. In the present embodiment, the second portion 42 is also provided on the FP electrode 14 and next to the first portion 41.

A dielectric constant of the second portion 42 is lower than a dielectric constant of the first portion 41. In the present embodiment, the first portion 41 is a silicon oxide film, and the second portion 42 is made of a material having a lower dielectric constant than a silicon oxide film. The second portion 42 is made of a material containing at least one of, for example, carbon-containing silicon oxide (SiOC) and carbon-containing silicon nitride (SiNC). In the present embodiment, the second portion 42 is not provided with a gap. That is, the second portion 42 is solid. The first portion 41 may be made of a material having a higher dielectric constant than that of a silicon oxide film. Then, the second portion 42 may be a silicon oxide film.

The second portion 42 is thinner than the first portion 41. That is, as shown in FIG. 2, a length w in the X-axis direction of the second portion 42 between the drift region 21 and the FP electrode 14 is shorter than a length h1 in the Z-axis direction of the first portion 41 between the drift region 21 and the FP electrode 14.

In the present embodiment, an upper end 42a of the second portion 42 is located above an upper end 14a of the FP electrode 14, that is, on the source electrode 12 side. A lower end of the second portion 42 is located at approximately the same height as a lower end of the first portion 41.

In the present embodiment, the first portion 41 of the FP insulating film 40 includes a lower portion 411 and an upper portion 412 disposed on the lower portion 411. The lower portion 411 is, for example, a thermal oxide film formed by thermal oxidation. In the present embodiment, the lower portion 411 is a thermally oxidized silicon oxide film. The upper portion 412 is, for example, a chemical vapor deposition (CVD) film formed by CVD. In the present embodiment, the upper portion 412 is a CVD silicon oxide film. The lower portion 411 may be a CVD film. The upper portion 412 may be a CVD film other than a CVD silicon oxide film. The upper portion 412 may not be provided. Then, to ensure a thickness of the first portion 41, the lower portion 411 may extend in the Z-axis direction to at least a part of a portion at which the upper portion 412 is disposed in FIG. 2.

As described above, the semiconductor device 1 according to the present embodiment includes the drain electrode 11, the source electrode 12, the semiconductor layer 2, the drift region 21 and the drain region 22 of the first conductivity type, the base region 23 of the second conductivity type, the source region 24 of the first conductivity type, the gate electrode 13, and the FP electrode 14. The semiconductor layer 2 is provided between the drain electrode 11 and the source electrode 12. The drift region 21 and the drain region 22 are provided in the semiconductor layer 2 and are located on the drain electrode 11. The base region 23 is provided in the semiconductor layer 2 and is located on the drift region 21. The source region 24 is provided in the semiconductor layer 2 and is located between the base region 23 and the source electrode 12. The gate electrode 13 is provided to face the base region 23 via the gate insulating film 31. The FP electrode 14 is provided in the drift region 21 via the FP insulating film 40 and is electrically connected to the source electrode 12. The FP insulating film 40 includes the first portion 41 and the second portion 42. The first portion 41 is located between the drift region 21 and the FP electrode 14 in the Z-axis direction from the drain electrode 11 to the source electrode 12. The second portion 42 is located between the drift region 21 and the FP electrode 14 in the X-axis direction perpendicular to the Z-axis direction. The dielectric constant of the second portion 42 in the FP insulating film 40 is lower than the dielectric constant of the first portion 41 in the FP insulating film 40.

In general, by thinning the insulating film, a capacitance of a capacitor in which an insulating film made of a material with a lower dielectric constant is interposed between electrodes becomes approximately the same as that of a capacitor in which an insulating film made of a material with a high dielectric constant is interposed between electrodes. In the present embodiment, the dielectric constant of the second portion 42 in the FP insulating film 40 is lower than the dielectric constant of the first portion 41. The length (shown as a width in FIG. 2) w of the second portion 42 in the X-axis direction is shorter than the length (height) h1 of the first portion 41 in the Z-axis direction. Accordingly, the second portion 42 can be made thinner than the first portion 41 while maintaining the same voltage distribution as when the second portion 42 is made of a material with the same dielectric constant as the first portion 41. Therefore, when the dielectric constant of the second portion 42 is lower than the dielectric constant of the first portion 41, the distance between the adjacent FP electrodes 14 (cell pitch) can be shortened. For example, when the material configuring the first portion 41 has a relative dielectric constant of about 3.9 and the material configuring the second portion 42 has a relative dielectric constant of about 3.0, the distance between the adjacent FP electrodes 14 can be shortened by about 10% compared to when the same material as that of the first portion 41 is used as the material of the second portion 42.

Therefore, according to the present embodiment, the distance between the adjacent FP electrodes 14 can be shortened, and as a result, an on-resistance of the semiconductor device 1 can be reduced.

In the present embodiment, the first portion 41 of the FP insulating film 40 is a silicon oxide film. Since a silicon oxide film has good film quality, by using a silicon oxide film for the first portion 41, it is possible to prevent a leakage current occurring between the FP electrode 14 and the drift region 21. More specifically, it is possible to reduce the leakage current occurring between a bottom of the FP electrode 14 at which a leakage current is likely to occur in the FP electrode 14 and the drift region 21. Although a thickness required for the first portion 41 increases by using a silicon oxide film for the first portion 41, the thickness of the first portion 41 does not affect the distance between the adjacent FP electrodes 14. Therefore, even when a silicon oxide film is used for the first portion 41, an effect of reducing the on-resistance of the semiconductor device 1 described above is not impaired.

In the present embodiment, the first portion 41 of the FP insulating film 40 includes the lower portion 411 and also the upper portion 412 provided on the lower portion 411. Accordingly, the thickness of the first portion 41 increases, and the leakage current that occurs between the FP electrode 14 and the drift region 21 can be further prevented.

In the present embodiment, the upper end 42a of the second portion 42 is located closer to the source electrode 12 than the upper end 14a of the FP electrode 14. Thus, a region of the second portion 42 having a low dielectric constant increases, and the distance between the adjacent FP electrodes 14 can be shortened.

### Method of Manufacturing Semiconductor Device 1

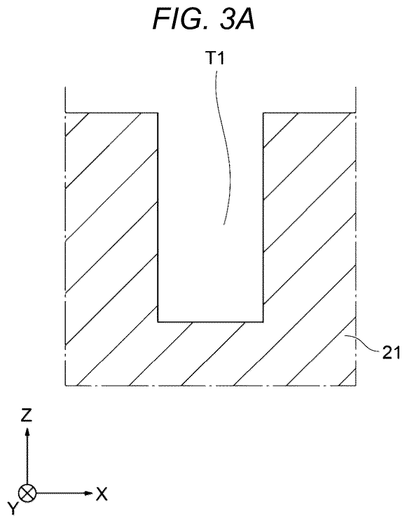

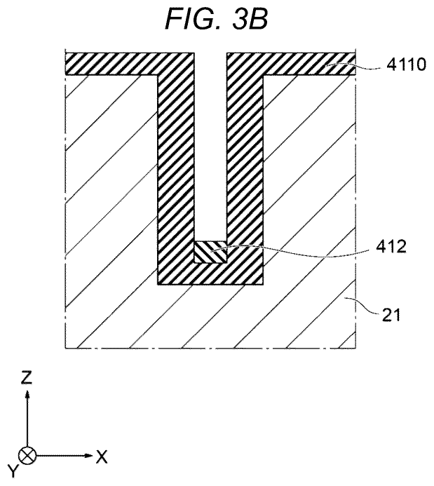

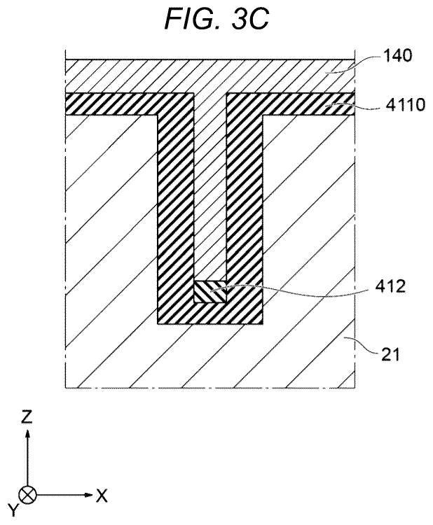

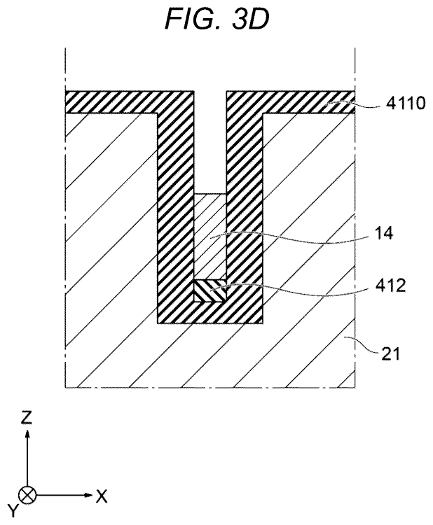

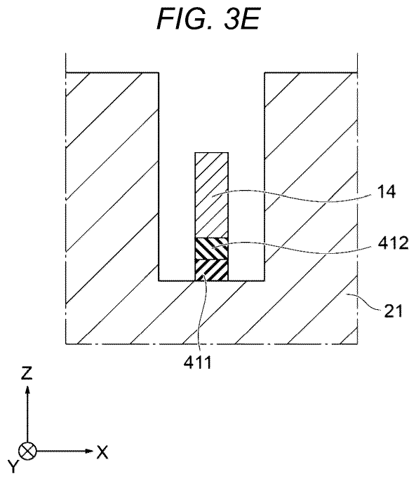

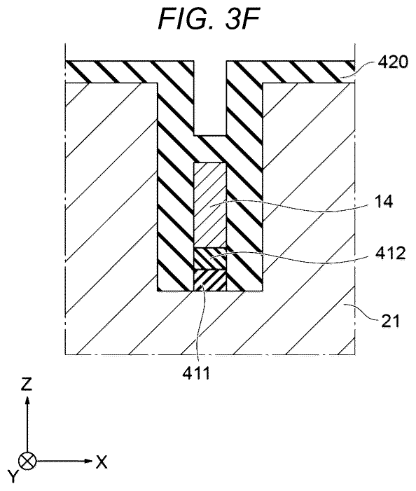

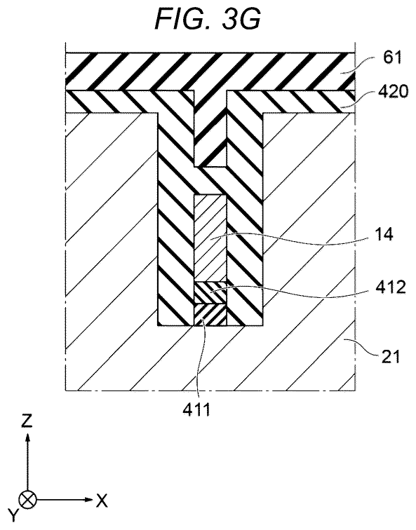

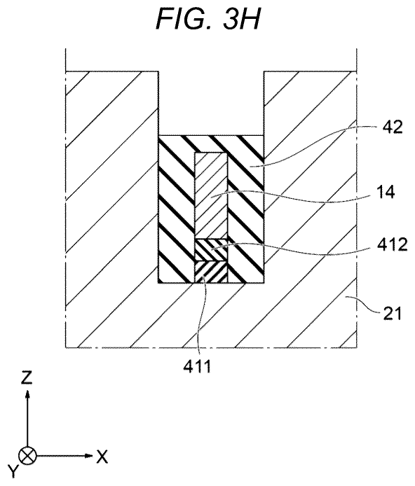

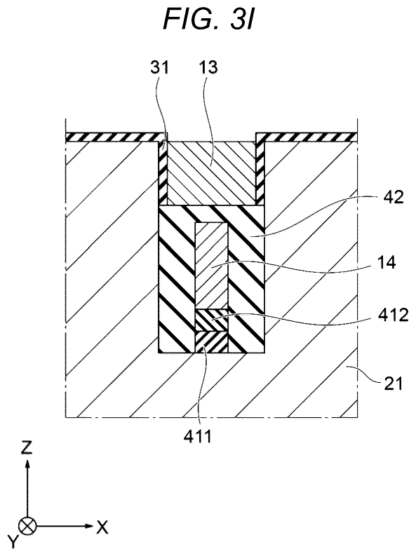

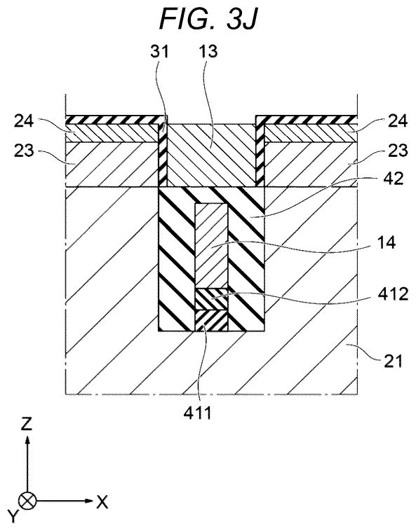

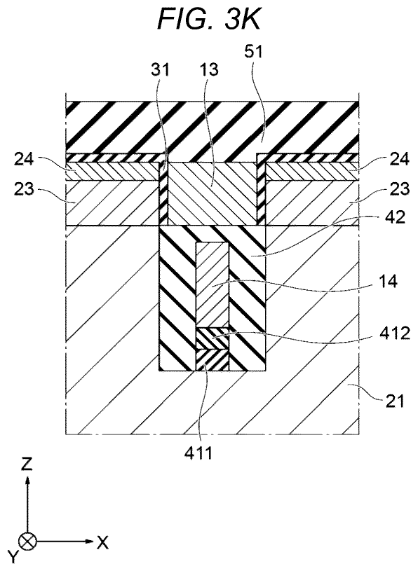

Next, an example of a method of manufacturing the semiconductor device 1 according to the present embodiment will be described with reference to FIGS. 3A to 3K. FIGS. 3A to 3K are cross-sectional views illustrating an example of a manufacturing process of the semiconductor device 1 according to the first embodiment, and correspond to an enlarged view of the region A1 in FIG. 1.

First, a semiconductor layer as shown in FIG. 3A is prepared. The semiconductor layer includes the drift region 21. The semiconductor layer also includes a trench T1 formed from the upper surface of the semiconductor layer to midway of the drift region 21. The trench T1 is formed, for example, by providing a hard mask such as a silicon oxide film on the upper surface of the semiconductor layer and then performing RIE or the like. The trench T1 is a portion into which the FP electrode 14, the FP insulating film 40, and the like are formed in subsequent processes.

Next, as shown in FIG. 3B, an insulating region 4110 is formed on an inner wall of the trench T1 and on the upper surface of the semiconductor layer by thermal oxidation, CVD, or the like. A part of the insulating region 4110 corresponds to the lower portion 411 described above. Then, an insulating material is deposited on a bottom of the insulating region 4110 by CVD or the like. The insulating material is, for example, silicon oxide. Accordingly, the upper portion 412 is formed. Note that the process of forming the upper portion 412 may be omitted.

Next, as shown in FIG. 3C, a conductive material is deposited on the upper surface of the semiconductor layer by CVD or the like. The conductive material is, for example, p-type or n-type polysilicon. Accordingly, a conductive portion 140 is formed on the upper portion 412 and on the upper surface of the semiconductor layer. A part of the conductive portion 140 corresponds to the FP electrode 14 described above.

Next, as shown in FIG. 3D, a part of the conductive portion 140 is removed by wet etching or the like. More specifically, a part located above the trench T1 and a part located on the upper surface of the semiconductor layer in the conductive portion 140 are removed. Thus, a part of the conductive portion 140 remains as the FP electrode 14.

Next, as shown in FIG. 3E, a part of the insulating region 4110 is removed by wet etching or the like. More specifically, all of the insulating region 4110 except for a part located directly under the upper portion 412 is removed. Thus, a part of the insulating region 4110 remains as the lower portion 411.

Next, as shown in FIG. 3F, an insulating material is deposited on the upper surface of the semiconductor layer by CVD or the like. The insulating material is a material having a lower dielectric constant than the material of the lower portion 411 such as carbon-containing silicon oxide or carbon-containing silicon nitride. Thus, an insulating region 420 is formed on the FP electrode 14, on a sidewall of trench T1, and on the upper surface of the semiconductor layer. A part of the insulating region 420 corresponds to the second portion 42 described above. In the present embodiment, the insulating region 420 is formed such that no gap is generated in at least a portion of the insulating region 420 that corresponds to the second portion 42.

Next, as shown in FIG. 3G, an insulating material is deposited on the upper surface of the semiconductor layer by CVD or the like. The insulating material is silicon oxide or silicon nitride. Thus, a sacrificial film 61 is formed above the FP electrode 14 and on the upper surface of the semiconductor layer. In the present embodiment, a recess portion of the insulating region 420 above the FP electrode 14 is filled with the sacrificial film 61.

Next, as shown in FIG. 3H, the sacrificial film 61 and a part of the insulating region 420 are removed by wet etching or the like. More specifically, the sacrificial film 61, a portion located above the trench T1 and a portion located in the upper surface of the semiconductor layer, of the insulating region 420, are removed. Thus, a part of the insulating region 420 remains as the second portion 42. In the present embodiment, the etching conditions are adjusted so that the insulating region 420 remains on the FP electrode 14. A portion of the insulating region 420 above the FP electrode 14 may be removed. Here, an insulating material is deposited on the FP electrode 14 by CVD or the like.

Next, as shown in FIG. 3I, the gate insulating film 31 is formed by thermal oxidation or the like. The gate insulating film 31 covers an upper sidewall of the trench T1 and the upper surface of the semiconductor layer. Thereafter, a conductive material such as polysilicon is deposited in the trench T1 by CVD or the like to form the gate electrode 13.

Next, as shown in FIG. 3J, p-type impurities are ion-implanted into the upper surface of the semiconductor layer to form the base region 23. Then, n-type impurities are ion-implanted into the upper surface of the semiconductor layer to form the source region 24.

Next, as shown in FIG. 3K, an insulating material is deposited on the upper surface of the semiconductor layer by CVD or the like. The insulating material is silicon oxide or silicon nitride. Thus, the interlayer insulating film 51 is formed above the gate electrode 13 and on the upper surface of the semiconductor layer.

Then, although not shown, by RIE or the like, a trench penetrating the gate insulating film 31 and the source region 24 and reaching midway of the base region 23 is formed. Next, p-type impurities are ion-implanted into the trench to form the high-concentration region 25.

Then, n-type impurities are ion-implanted into a lower surface of the semiconductor layer to form the drain region 22. Thereafter, the drain electrode 11 is formed on the lower surface of the semiconductor layer, and the source electrode 12 including the contact portion 12a is formed on the upper surface of the semiconductor layer.

By the above processes, the semiconductor device 1 is manufactured.

In the process of removing a part of the insulating region 4110 described in FIG. 3E, a part of the insulating region 4110 may remain at the bottom of the trench T1 by changing the conditions for etching and the like. Below, Modifications 1 and 2 of the first embodiment in which a part of the insulating region 4110 remains at the bottom of the trench T1 will be described.

### Modification 1 of First Embodiment

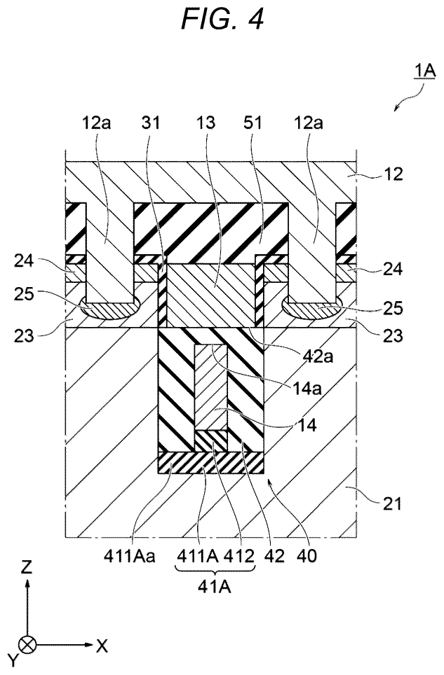

FIG. 4 is a cross-sectional view of a semiconductor device 1A according to Modification 1 of the first embodiment, and corresponds to an enlarged view of the region A1 in FIG. 1. The present modification corresponds to a case where a part of the insulating region 411 with a uniform thickness remains on the bottom surface of the trench T1 in the process of FIG. 3E.

As shown in FIG. 4, in the present modification, a first portion 41A of the FP insulating film 40 includes an extension portion 411Aa disposed below the second portion 42 of the FP insulating film 40 and extending in the X-axis direction. In the present modification, the extension portion 411Aa is made of the same material as a lower portion 411A. In other words, the first portion 41A includes the lower portion 411A and the upper portion 412, and the lower portion 411A includes the extension portion 411Aa extending in the X-axis direction between the second portion 42 and the drift region 21.

In the present modification, a thickness of the lower portion 411A, that is, a length of the lower portion 411A in the Z-axis direction is uniform. In other words, an upper end of the extension portion 411Aa is located at approximately the same height as a boundary between the lower portion 411A and the upper portion 412.

According to the present modification, the extension portion 411Aa has a relatively high dielectric constant, so that a leakage current between a corner of the FP electrode 14 on a lower side (that is, the drain electrode 11 side) and the drift region 21 can be further prevented.

### Modification 2

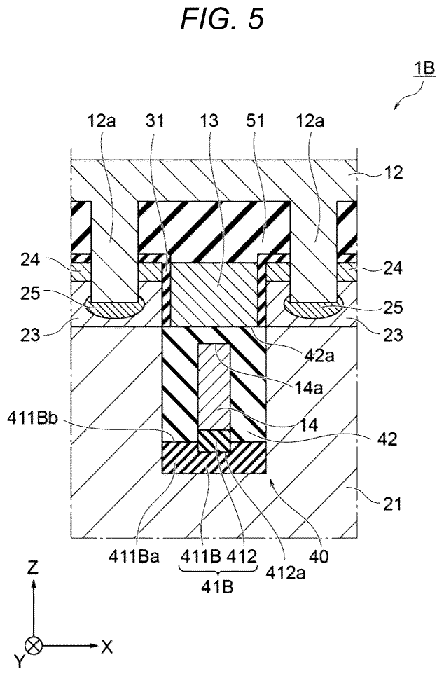

FIG. 5 is a cross-sectional view of a semiconductor device 1B according to Modification 2 of the first embodiment, and corresponds to an enlarged view of the region A1 in FIG. 1. The present modification corresponds to a case where a part of the insulating region 4110 also remains on the side of the upper portion 412 in the above-described Modification 1 of the first embodiment.

As shown in FIG. 5, in the present modification, a first portion 41B of the FP insulating film 40 includes an extension portion 411Ba disposed below the second portion 42 of the FP insulating film 40 and extending in the X-axis direction. In the present modification, the extension portion 411Ba is made of the same material as the lower portion 411A. In other words, the first portion 41B includes a lower portion 411B and the upper portion 412, and the lower portion 411B includes the extension portion 411Ba extending in the X-axis direction between the second portion 42 and the drift region 21.

In the present modification, the extension portion 411Ba is also provided on a side of the upper portion 412. In other words, an upper end 411Bb of the extension portion 411Ba is located closer to the source electrode 12 than a lower end 412a of the upper portion 412. The extension portion 411Ba may also be provided on a part of a side of the FP electrode 14. That is, the upper end 411Bb of the extension portion 411Ba may be located closer to the source electrode 12 than an upper end of the upper portion 412.

According to the present modification, the extension portion 411Ba is also provided on the side of the upper portion 412, so that a leakage current between a corner on the lower side of the FP electrode 14 and the drift region 21 can be further prevented.

### Second Embodiment

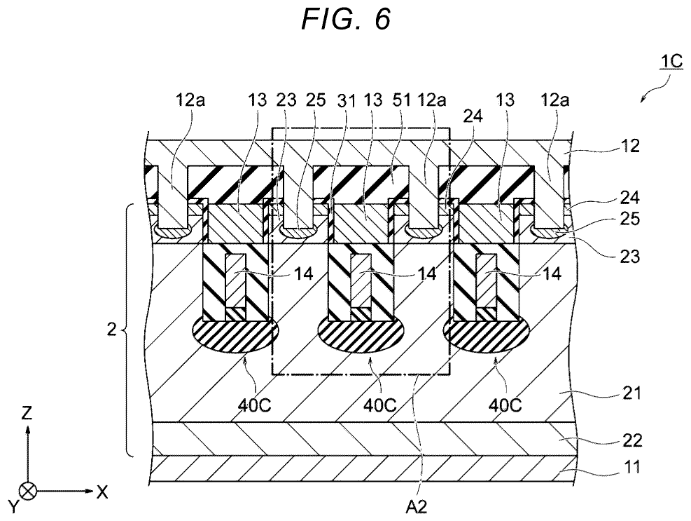

Hereinafter, a second embodiment will be described with reference to FIG. 6. FIG. 6 is a cross-sectional view of a semiconductor device 1C according to the second embodiment. As shown in FIG. 6, the semiconductor device 1C according to the present embodiment includes a flask-shaped FP insulating film 40C instead of the FP insulating film 40 of the first embodiment.

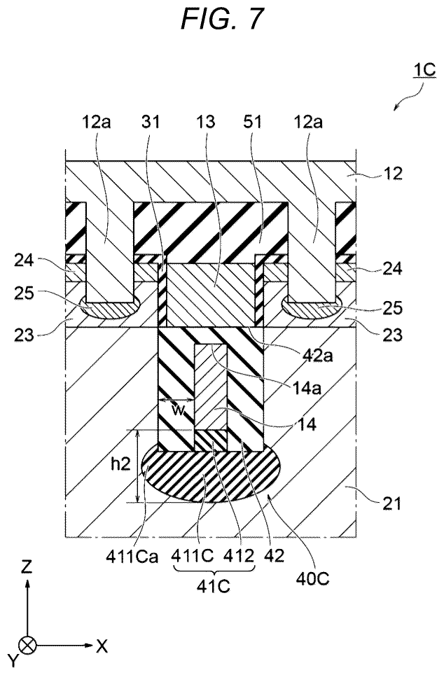

FIG. 7 is an enlarged view of a region A2 in FIG. 6. Parts of the left and right FP insulating films 40C are inserted into the region A2 in FIG. 6, but are not shown in FIG. 7.

As shown in FIG. 7, the FP insulating film 40C includes a first portion 41C. The first portion 41C bulges out in the X-axis direction more than the second portion 42. More specifically, the first portion 41C of the FP insulating film 40C includes a bulging portion 411Ca that bulges out in the X-axis direction more than a side end of the second portion 42 of the FP insulating film 40C. In the present embodiment, the bulging portion 411Ca is made of the same material as a lower portion 411C. In other words, the first portion 41C includes the lower portion 411C and the upper portion 412, and the lower portion 411C includes the bulging portion 411Ca.

In the present embodiment, as in the first embodiment, the second portion 42 is thinner than the first portion 41C. That is, the length w in the X-axis direction of the second portion 42 between the drift region 21 and the FP electrode 14 is shorter than a length h2 in the Z-axis direction of the first portion 41 between the drift region 21 and the FP electrode 14.

According to the present embodiment, the length h2 is longer than the length h1 in the first embodiment. That is, the thickness of the first portion 41 of the FP insulating film 40 is increased, so that the leakage current between the FP electrode 14 and the drift region 21 can be further prevented. More specifically, the leakage current between the bottom of the FP electrode 14 and the drift region 21 can be further prevented.

### Method of Manufacturing Semiconductor Device 1C

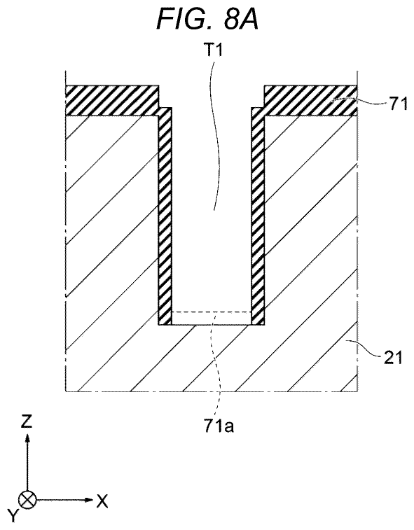

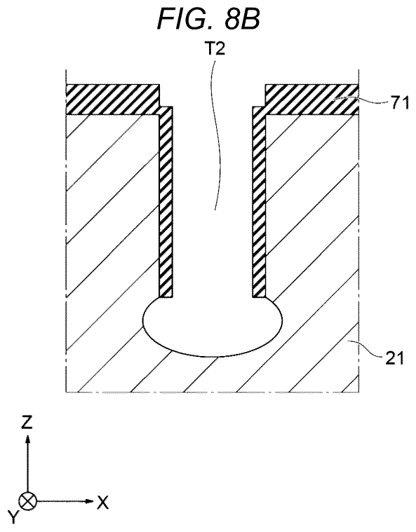

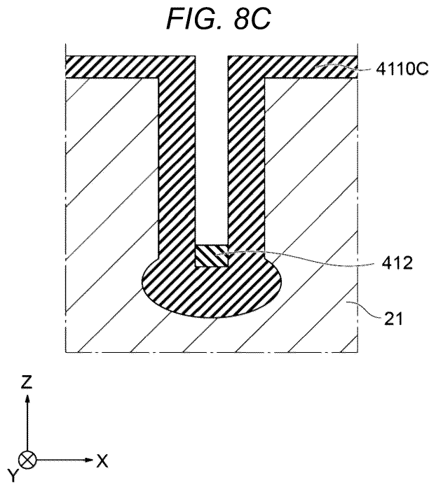

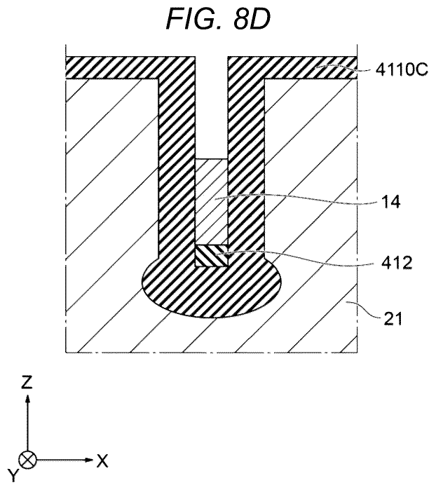

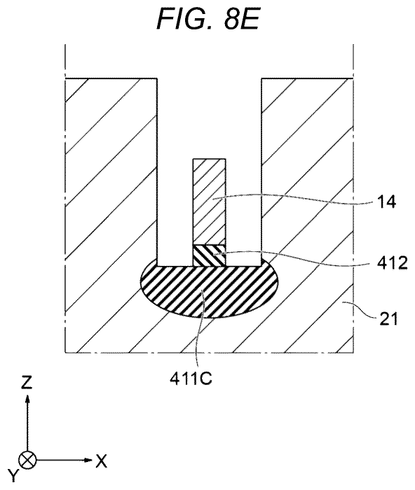

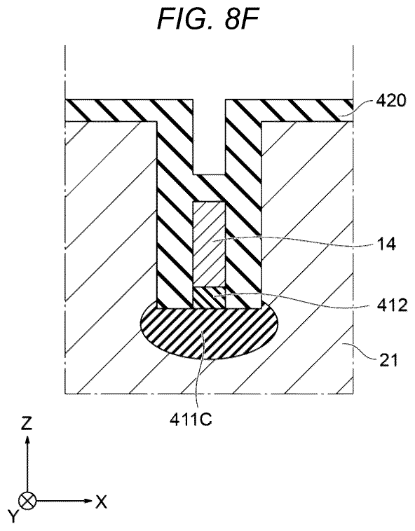

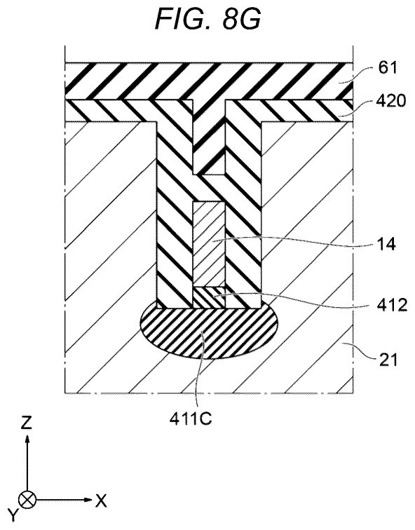

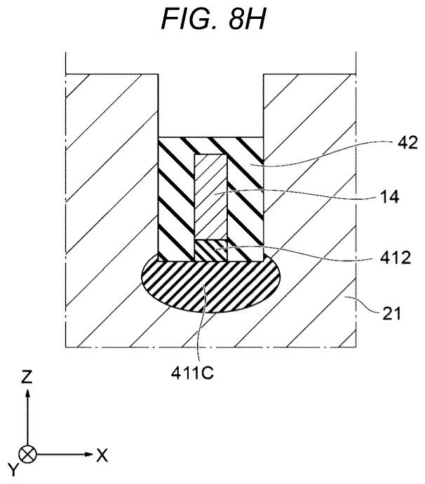

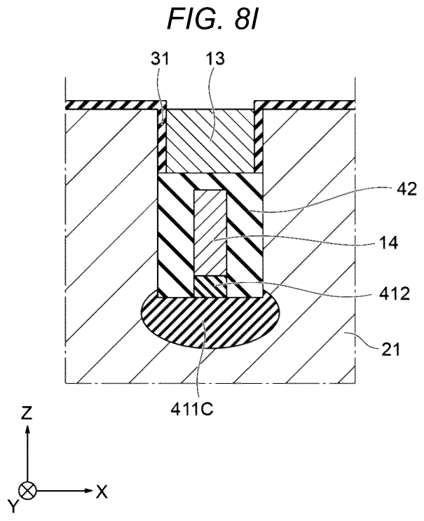

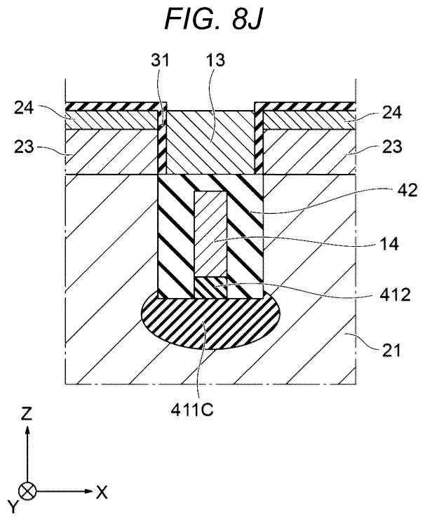

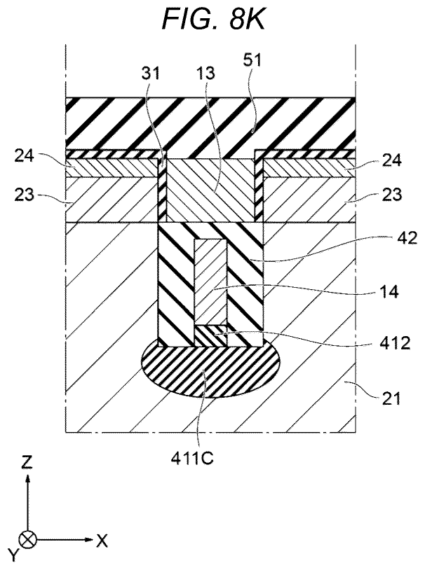

Next, an example of a method of manufacturing the semiconductor device 1C according to the present embodiment will be described with reference to FIGS. 8A to 8K. FIGS. 8A to 8K are cross-sectional views illustrating an example of a manufacturing process of the semiconductor device 1C according to the second embodiment, and correspond to an enlarged view of the region A2 in FIG. 6.

First, when preparing the semiconductor layer shown in FIG. 3A, a hard mask used to form the trench T1 remains on the upper surface of the semiconductor layer.

Next, as shown in FIG. 8A, a sacrificial oxide film is formed on an inner wall of the trench T1 by thermal oxidation or the like. Thus, an insulating region 71 is formed. The insulating region 71 is a region in which the hard mask that remains on the upper surface of the semiconductor layer and the sacrificial oxide film are combined. Since the hard mask remains, a thickness of a part of the insulating region 71 located on the upper surface of the semiconductor layer is thicker than a thickness of a part of the insulating region 71 located on the inner wall of the trench T1. Then, a portion 71a of the insulating region 71 located at the bottom of the trench T1 is removed by RIE or the like. Thus, the bottom of the trench T1 is exposed.

Next, as shown in FIG. 8B, the bottom of the trench T1 is expanded by isotropic etching such as wet etching to form a trench T2. More specifically, the trench T2 includes an upper portion with the same width as the trench T1, and a lower portion having a flask-like shape wider than the trench T1. The lower portion of the trench T2 is a portion in which the above-described lower portion 411C is to be formed in a later process. Then, the insulating region 71 is removed by wet etching or the like.

Next, as shown in FIG. 8C, an insulating region 4110C is formed on an inner wall of the trench T2 and the upper surface of the semiconductor layer by thermal oxidation or CVD or the like. A part of the insulating region 4110C corresponds to the lower portion 411C. Then, an insulating material is deposited on the bottom of the insulating region 4110C by CVD or the like. The insulating material is, for example, silicon oxide. Accordingly, the upper portion 412 is formed.

Next, as shown in FIG. 8D, the FP electrode 14 is formed. More specifically, first, a conductive material is deposited on the upper surface of the semiconductor layer by CVD or the like. The conductive material is, for example, p-type or n-type polysilicon. Accordingly, a conductive portion is formed on the upper portion 412 and on the upper surface of the semiconductor layer. Then, a portion located above the trench T2 and a portion located on the upper surface of the semiconductor layer in the conductive portion are removed. Thus, a part of the conductive portion remains as the FP electrode 14.

Next, as shown in FIG. 8E, a part of the insulating region 4110C is removed by wet etching or the like. More specifically, all of the insulating region 4110C except for a part located below the lower end of the upper portion 412 is removed. Thus, the rest of the parts of the insulating region 4110C remains as the lower portion 411C. As in Modification 2 of the first embodiment described above, portions of the insulating region 4110C located on sides of the upper portion 412 may remain.

The subsequent processes are the same as those in the first embodiment. More specifically, the processes shown in FIGS. 8F to 8K are the same as those shown in FIGS. 3F to 3K, respectively. After the process shown in FIG. 8K, the high-concentration region 25, the drain region 22, the drain electrode 11, and the source electrode 12 are formed by the same processes as those in the first embodiment.

By the above processes, the semiconductor device 1C is manufactured.

According to the manufacturing method of the present embodiment, the hard mask used to form the trench T1 remains on the upper surface of the semiconductor layer, and then the sacrificial oxide film is formed on the inner wall of the trench T1. Accordingly, the thickness of the portion of the insulating region 71 located on the upper surface of the semiconductor layer increases, and the upper surface of the semiconductor layer is prevented from being exposed when removing the portion 71a.

According to the manufacturing method of the present embodiment, by removing the insulating region 71 after forming the trench T2, the insulating region 4110C having a uniform thickness can be formed. Therefore, in the process of removing a part of the insulating region 4110C by wet etching or the like, the conditions when the lower portion 411C remains can be eased, and the process can be simplified.

### Modification of Second Embodiment

In the second embodiment described above, the thickness of the first portion 41C can be ensured without providing the upper portion 412, so that the upper portion 412 may not be provided. Hereinafter, a modification of the second embodiment in which the upper portion 412 is omitted in the second embodiment will be described.

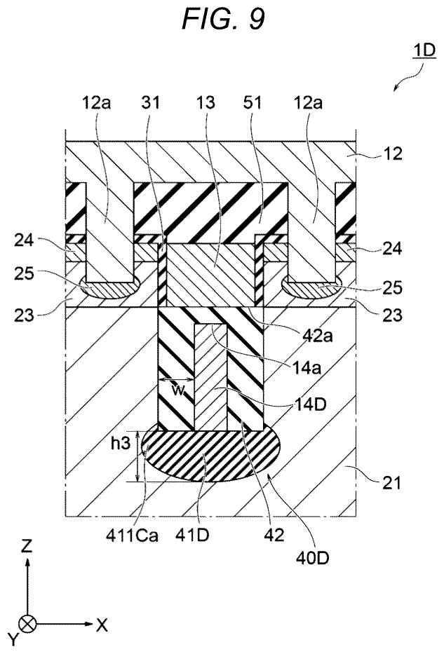

FIG. 9 is a cross-sectional view of a semiconductor device 1D according to Modification of the second embodiment, and corresponds to an enlarged view of the region A2 in FIG. 6. As shown in FIG. 9, in the present modification, the upper portion 412 of the first portion is omitted. That is, an FP insulating film 40D includes a first portion 41D and the second portion 42. The first portion 41D of the FP insulating film 40D includes a part corresponding to the lower portion 411C of the second embodiment, but does not include a part corresponding to the upper portion 412. In the present modification, a part of an FP electrode 14D is provided in a portion at which the upper portion 412 is disposed in the second embodiment.

In the present modification, as in the second embodiment, the second portion 42 is thinner than the first portion 41D (more precisely, the first portion 41D directly under the FP electrode 14D). That is, the length w in the X-axis direction of the second portion 42 between the drift region 21 and the FP electrode 14 is shorter than a length h3 in the Z-axis direction of the first portion between the drift region 21 and the FP electrode 14.

According to the present modification, the process of forming the upper portion 412 can be omitted.

In each of the above-described embodiments, the semiconductor device 1 is a so-called stripe-type MOSFET including the FP electrode 14 extending in the Y-axis direction. However, the semiconductor device 1 is not limited thereto and may be a so-called dot-type MOSFET including an FP electrode provided in a dot shape.

In each of the above-described embodiments, the semiconductor device 1 has a trench gate structure in which a gate electrode is provided in a trench. However, the semiconductor device 1 is not limited thereto and may have a planar gate structure in which a gate electrode is provided on a main surface of the semiconductor layer 2.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A field plate MOSFET semiconductor device comprising:
a first electrode having a main surface that extends along a second direction;
a second electrode;
a semiconductor layer between the first electrode and the second electrode;
a gate electrode at least partially disposed in the semiconductor layer;
a field plate electrode disposed in a region of the semiconductor layer between the gate electrode and the first electrode, the field plate being electrically connected to the second electrode; and
a field plate insulating region that includes
a first insulating material disposed along a bottom of the field plate electrode oriented along the second direction, and
a second insulating material disposed along at least a portion of a side of the field plate electrode in a first direction perpendicular to the second direction, wherein
a dielectric constant of the second insulating material is lower than a dielectric constant of the first insulating material.

2. The field plate MOSFET according to claim 1, wherein the side of field plate electrode in the first direction is longer than a width of the field plate electrode in the second direction.

3. The field plate MOSFET according to claim 1, wherein along the side of the field plate electrode, a length of the second insulating material in the first direction is longer than a width of the second insulating material in the second direction.

4. The field plate MOSFET according to claim 1, wherein along the side of the field plate electrode, a width of the second insulating material in the second direction is shorter in length than a height of the first insulating material in the first direction.

5. The field plate MOSFET according to claim 1, further comprising a gate insulation region disposed at least partially along a side of the gate electrode.

6. The field plate MOSFET according to claim 1, wherein the first insulating material includes a first portion that is disposed below the bottom of the field plate electrode, and an extension portion that is disposed below the first portion of the first insulating material and extends in the second direction past an edge of the first portion.

7. The field plate MOSFET according to claim 1, wherein the first insulating material includes a bulging portion that bulges out further in the second direction than a side of the second insulating material.

8. The field plate MOSFET according to claim 1, wherein the semiconductor layer comprising:
a first semiconductor region of a first conductivity type located on the first electrode,
a second semiconductor region of a second conductivity type located on the first semiconductor region, and
a third semiconductor region of the first conductivity type located between the second semiconductor region and the second electrode.

9. The field plate MOSFET according to claim 1, wherein the first insulating material includes a lower portion that is a thermal oxide film and an upper portion that is disposed above the lower portion and is a CVD film.

10. The field plate MOSFET according to claim 1, wherein an upper end of the second insulating material is located closer to the second electrode than an upper end of the field plate electrode.

11. The field plate MOSFET according to claim 1, wherein
the second insulating material comprises a silicon oxide film, and
the first insulating material comprises a material having a lower dielectric constant than the silicon oxide film.

12. The field plate MOSFET according to claim 11, wherein the second insulating material comprises a material containing at least one of carbon-containing silicon oxide and carbon-containing silicon nitride.

13. The field plate MOSFET according to claim 1, wherein the second insulating material does not include a gap.

14. The field plate MOSFET according claim 1, wherein the second insulating material is located above the first insulating material in the second direction with respect to the main surface of the first electrode.

15. A field plate MOSFET semiconductor device comprising:
a first electrode having a main surface that extends along a second direction;
a second electrode;
a semiconductor layer between the first electrode and the second electrode;
a gate electrode at least partially disposed in the semiconductor layer;
a field plate electrode disposed in a region of the semiconductor layer between the gate electrode and the first electrode, the field plate being electrically connected to the second electrode, and the field plate having a longer dimension in a first direction than in the second direction, the first direction being perpendicular to the second direction; and
a field plate insulating region that includes
at least one first insulating material disposed along a bottom of the field plate electrode and oriented along the second direction, and
a second insulating material disposed along at least a portion of a side of the field plate electrode in the first direction, wherein
a dielectric constant of the second insulating material is lower than a dielectric constant of the at least one first insulating material.

16. The field plate MOSFET according to claim 15, wherein the at least one first insulating material includes a first portion that is disposed below the bottom of the field plate electrode, and an extension portion that is below the first portion of the first insulating material and extends in the first direction beyond the first portion.

17. The field plate MOSFET according to claim 15, wherein the at least one first insulating material includes a bulging portion that bulges out further in the second direction than a side end of the second insulating material.

18. The field plate MOSFET according to claim 15, wherein the at least one first insulating material includes a lower portion that is a thermal oxide film and an upper portion that is disposed above the lower portion and is a CVD film.

19. The field plate MOSFET according to claim 15, wherein
the second insulating material comprises a silicon oxide film, and
the at least one first insulating material has a lower dielectric constant than the silicon oxide film.

20. The field plate MOSFET according to claim 19, wherein the at least one first insulating material comprises a material containing at least one of carbon-containing silicon oxide and carbon-containing silicon nitride.
